(19) United States
(12) Patent Application Publication
(10) Pub. No.: US 2024/0194745 A1
(43) Pub. Date: Jun. 13, 2024

(54) SEMICONDUCTOR DEVICE HAVING A SHIELDING LAYER AND A METHOD OF FABRICATING THE SEMICONDUCTOR DEVICE

(71) Applicant: Infineon Technologies Austria AG, Villach (AT)

(72) Inventors: Ling Ma, Redondo Beach, CA (US); Robert Haase, San Pedro, CA (US); Timothy Henson, Mount Shasta, CA (US)

(21) Appl. No.: 18/078,597

(22) Filed: Dec. 9, 2022

(51) Int. Cl. H01L 29/40; H01L 21/8234; H01L 23/522; H01L 23/528; H01L 23/532; H01L 27/088; H01L 29/06; H01L 29/423

(52) U.S. Cl. CPC H01L 29/407; H01L 21/823475; H01L 23/5226; H01L 23/5283; H01L 23/53266; H01L 27/088; H01L 29/0607; H01L 29/0696; H01L 29/401; H01L 29/4236

(57) ABSTRACT

A semiconductor device includes: a semiconductor substrate; a plurality of transistors cells in an active device region of the semiconductor substrate, each transistor cell having a gate electrode separated from the semiconductor substrate by a gate dielectric; a plurality of needle-shaped field plate trenches in the active device region and in a termination region of the semiconductor substrate that is devoid of fully functional transistor cells; a polysilicon layer that forms the gate electrodes in the active device region and extends over at least part of the termination region; and a shielding layer that separates the polysilicon layer from the semiconductor substrate in the termination region, the shielding layer having a higher dielectric strength than just the gate dielectric. A method of producing the semiconductor device is also described.

### BACKGROUND

Many types of power semiconductor devices utilize trench field plates for improving the breakdown and Rdson (on-state resistance) characteristics of the device. In some cases, the field plate trenches are ‘needle-shaped’ meaning the trench structure is narrow and long in a depth-wise direction of the semiconductor substrate in which the device is formed, as opposed to stripe-shaped trenches which have a longest linear dimension in a direction transverse to the depth-wise direction of the semiconductor substrate. In needle trench technologies, connecting the gate pad of the device to the gate electrodes in the active trenches is difficult due to termination structures having arrays of needle structures. The gate connection is typically implemented by a tungsten layer patterned with lithography and etch steps above the interlayer dielectric formed on the semiconductor substrate, and requires another layer of dielectric film above the tungsten layer with more lithography and etch steps.

Thus, there is a need for an improved design for connecting the gate pad of a semiconductor device with needle-shaped field plate trenches to the gate electrodes in the active trenches.

### SUMMARY

According to an embodiment of a semiconductor device, the semiconductor device comprises: a semiconductor substrate; a plurality of transistors cells in an active device region of the semiconductor substrate, each transistor cell having a gate electrode separated from the semiconductor substrate by a gate dielectric; a plurality of needle-shaped field plate trenches in the active device region and in a termination region of the semiconductor substrate that is devoid of fully functional transistor cells; a polysilicon layer that forms the gate electrodes in the active device region and extends over at least part of the termination region; and a shielding layer that separates the polysilicon layer from the semiconductor substrate in the termination region, the shielding layer having a higher dielectric strength than just the gate dielectric.

According to another embodiment of a semiconductor device, the semiconductor device comprises: a semiconductor substrate having an edge that extends between first and second main surfaces of the semiconductor substrate; a plurality of gate trenches extending from the first main surface into the semiconductor substrate in an active device region of the semiconductor substrate, each gate trench including a gate electrode insulated from the semiconductor substrate by a gate dielectric; a plurality of needle-shaped field plate trenches extending from the first main surface into the semiconductor substrate in both the active device region and a termination region of the semiconductor substrate that is devoid of fully functional transistor cells, the termination region having a recess formed in the first main surface; a shielding layer disposed in the recess in the termination region, the shielding layer having a higher dielectric strength than just the gate dielectric; polysilicon disposed in recesses formed in the shielding layer, the polysilicon being insulated from the semiconductor substrate by the shielding layer and electrically connected to the gate electrodes in the active device region.

According to an embodiment of a method of fabricating semiconductor devices from a semiconductor wafer, the method comprises: forming a plurality of transistors cells in an active device region of the semiconductor substrate, each transistor cell having a gate electrode separated from the semiconductor substrate by a gate dielectric; forming a plurality of needle-shaped field plate trenches in the active device region and in a termination region of the semiconductor substrate that is devoid of fully functional transistor cells; forming a polysilicon layer that forms the gate electrodes in the active device region and extends over at least part of the termination region; and forming a shielding layer that separates the polysilicon layer from the semiconductor substrate in the termination region, the shielding layer having a higher dielectric strength than just the gate dielectric.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial cross-sectional view of a semiconductor device having an improved gate interconnection design.

FIGS. 2A through 2K illustrate the same partial cross-sectional view of the semiconductor device in FIG. 1 during different stages of production, according to an embodiment.

FIG. 3 illustrates a partial cross-sectional view of a semiconductor device having an improved gate interconnection design, according to another embodiment.

FIG. 4 illustrates a partial cross-sectional view of a semiconductor device having an improved gate interconnection design, according to another embodiment.

### DETAILED DESCRIPTION

The embodiments described herein provide a gate interconnection design for semiconductor devices with needle-shaped field plate trenches. The gate interconnection design includes a polysilicon layer that forms the gate electrodes in an active device region of a semiconductor substrate and extends over at least part of a termination region of the semiconductor substrate. A shielding layer separates the polysilicon layer from the semiconductor substrate in the termination region. The shielding layer has a higher dielectric strength than just the gate dielectric that separates the gate electrodes in the active device region from the semiconductor substrate. The gate interconnection design avoids a costly tungsten gate interconnection layer and the overlying dielectric film. The termination structure described herein has a region of sub-surface dielectric material that shields the gate (e.g., polysilicon) material from exposure to the high voltage of the drain.

Described next with reference to the figures are embodiments of the gate interconnection design and methods of producing the gate interconnection design.

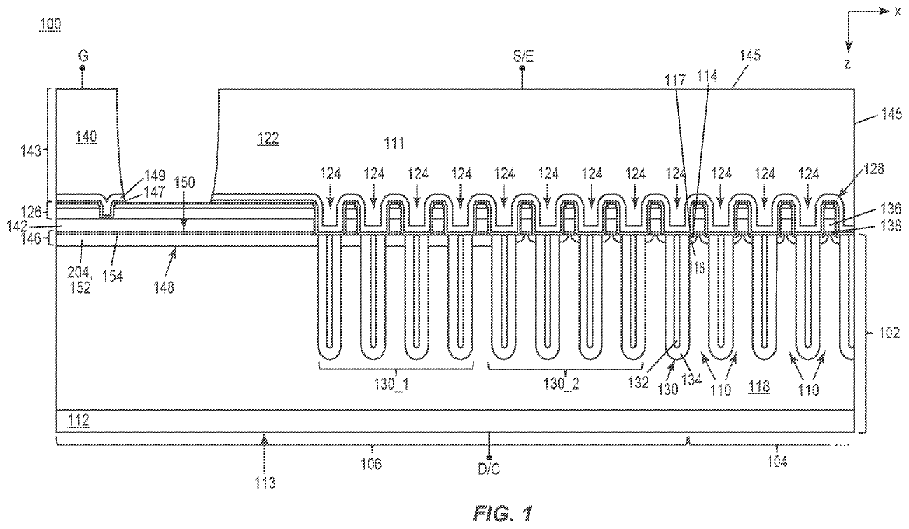

FIG. 1 illustrates a partial cross-sectional view of a semiconductor device 100 with the gate interconnection design. The semiconductor device 100 includes a semiconductor substrate 102. The semiconductor substrate 102 comprises one or more semiconductor materials that are used to form power semiconductor devices such as, e.g., Si or SiC power MOSFETs (metal-oxide-semiconductor field-effect transistors). For example, the semiconductor substrate 102 may comprise Si, silicon carbide (SiC), germanium (Ge), silicon germanium (SiGe), gallium nitride (GaN), gallium arsenide (GaAs), and the like. The semiconductor substrate 100 may include one or more epitaxial layers.

The semiconductor substrate 102 includes an active device region 104 and a termination region 106 that separates the active device region 104 from an edge 108 of the semiconductor substrate 102, the edge 108 extending between first and second main surfaces 111, 113 of the semiconductor substrate 102. The active device region 104 is where fully functional device cells are formed. The termination region 106 is devoid of fully functional device cells and reduces electrical field crowding at termination.

Transistor cells 110 are formed in the active device region 104. The transistor cells 110 are electrically coupled in parallel to form a vertical power transistor such as a vertical power MOSFET, an IGBT (insulated gate bipolar transistor), a JFET (junction FET), etc. Only a few transistor cells 110 are shown in the partial view of FIG. 1. In general, the semiconductor device 100 may have tens, hundreds, thousands, or even more transistors cells 110.

In the case of a vertical power transistor, a drain or collector 112 of the vertical power transistor is disposed at the backside of the semiconductor substrate 102. Each transistor cell 110 includes a source/emitter region 114 of a first conductivity type and a body region 116 of a second conductivity type opposite the first conductivity type. The source/emitter region 114 of each transistor cell 110 of the first type is separated from a drift zone 118 of the first conductivity type by the corresponding body region 116.

The first conductivity is n-type and the second conductivity type is p-type for an n-channel device formed by the transistor cells 110, whereas the first conductivity is p-type and the second conductivity type is n-type for a p-channel device formed by the transistor cells 110. For either an n-channel device or a p-channel device, the source/emitter region 114 and the body region 116 form part of a transistor cell 110 and the transistor cells 110 are electrically connected in parallel between source (S)/emitter (E) and drain (D)/collector (C) terminals of the semiconductor device 100 to form a power transistor.

The body regions 116 of the transistor cells 110 may include a body contact region 117 of the second conductivity type and having a higher doping concentration than the body regions 116, to provide an ohmic connection with a source/emitter metallization 122 through a contact structure 124 that extends through an interlayer dielectric 126 that separates the source/emitter metallization 122 from the semiconductor substrate 102. The source/emitter regions 114 of the transistor cells 110 are also electrically connected to the source/emitter metallization 122 through the contact structure 124.

Each transistor cell 110 of the semiconductor device 100 also includes gate structures 128, with needle-shaped field plate trenches 130 between neighboring ones of the gate structures 128. The term ‘needle-shaped’ as used herein means a structure that is narrow and long in a depth-wise direction (z direction in FIG. 1) of the semiconductor substrate 102. For example, the needle-shaped field plate trenches 130 may resemble a needle, column or spicule in the depth-wise direction of the semiconductor substrate 102.

The needle-shaped field plate trenches 130 extend from the first main surface 111 of the semiconductor substrate 102 and into the semiconductor substrate 102 in both the active device region 104 and the termination region 106. Field plates 132 are disposed in the needle-shaped field plate trenches 130 and electrically connected to the source/emitter metallization 122 through the contact structure 124. A field dielectric insulating material 134 separates the field electrodes 132 from the semiconductor material of the semiconductor substrate 102.

In FIG. 1, the gate structures 128 are illustrated as planar gate structures in that the corresponding gate electrodes 136 are disposed above the first main surface 111 of the semiconductor substrate 102. The gate structures 128 instead may be trench gate structures in that the gate electrodes 136 are disposed in trenches (not shown) formed in the first main surface 111 of the semiconductor substrate 102. In either case, the gate electrodes 136 are separated from the semiconductor substrate 102 by a gate dielectric 138.

The gate electrodes 136 in the active device region 104 of the semiconductor substrate 102 are electrically connected to a gate terminal (G) through, e.g., a gate metallization 140 and a (gate) polysilicon layer 142. The gate metallization 140 may be part of a structured power metallization 143 that also includes the source/emitter metallization 122 which is separated from the gate metallization 140. The structured power metallization 143 may include a thick power metal layer 145 that comprises Cu, Al, AlCu, AlSiCu, etc., a diffusion barrier and/or adhesion promoter 147 such as Ti and/or TiN below the thick power metal layer 145, and a tungsten layer 149 between the thick power metal layer 145 and the diffusion barrier and/or adhesion promoter 147.

The gate polysilicon layer 142 is disposed below the structured power metallization and forms the gate electrodes 136 in the active device region 104 and extends over at least part of the termination region 106. A shielding layer 146 separates the gate polysilicon layer 142 from the semiconductor substrate 102 in the termination region 106 and has a higher dielectric strength than just the gate dielectric 138.

In one embodiment, the first main surface 111 of the semiconductor substrate 102 has a recess 148 in the termination region 106 and the shielding layer 146 is an oxide disposed in the recess 148. For example, the shielding layer 146 may be an STI (shallow trench isolation) oxide. The first main surface 111 of the semiconductor substrate 102 and the upper surface 150 of the shielding layer oxide 146 may be coplanar and the gate polysilicon layer 142 may lie in the same plane above both the active device region 104 and the termination region 106, e.g., as shown in FIG. 1. For example, the shielding layer oxide 146 may be planarized, e.g., by CMP (chemical-mechanical polishing) so as to be coplanar with the first main surface 111 of the semiconductor substrate 102. According to this embodiment, the gate polysilicon layer 142 does not step down from the termination region 106 to the active device region 104. In another embodiment, the shielding layer 146 is an oxide formed by LOCOS (local oxidation of silicon). According to this embodiment, the shielding layer oxide 146 is disposed partly below the first main surface 111 of the semiconductor substrate 102 and partly above the first main surface 111 in the termination region 106.

Separately or in combination, the shielding layer 146 may comprise a first oxide 152 that contacts the semiconductor substrate 102 in the termination region 106 and a second oxide 154 formed on the first oxide 152. If the gate oxide 138 is deposited, the second oxide 154 of the shielding layer 146 may be identical to the gate oxide 138. If, however, the gate oxide 138 is thermally grown, then the gate oxide 138 is at interface of the substrate 102 and the shielding layer 146 and the second oxide 154 of the shielding layer 146 may be different than the gate oxide 138. The gate oxide 138 instead may be a mixture of thermal and deposited oxide, such that part of the second oxide 154 of the shielding layer 146 may be identical to the gate oxide 138 and another part of the second oxide 154 may be different than the gate oxide 138.

As shown in FIG. 1, at least some of the needle-shaped field plate trenches 130 in the termination region 106 may extend through the shielding layer 146. For example, a first subset 130_1 of the needle-shaped field plate trenches 130 in the termination region 106 may extend through the shielding layer 146 and a second subset 130_2 of the needle-shaped field plate trenches 130 in the termination region 106 may extend only in semiconductor material of the substrate 102.

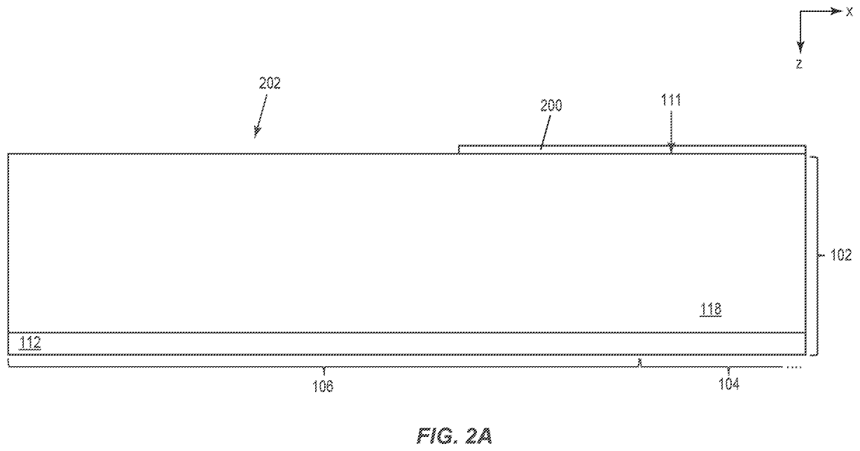

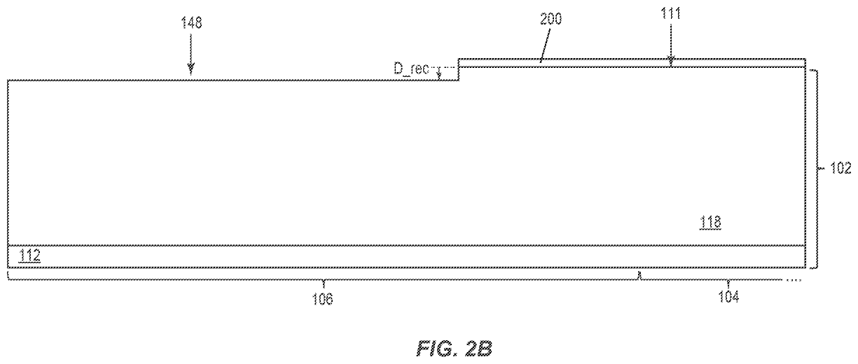

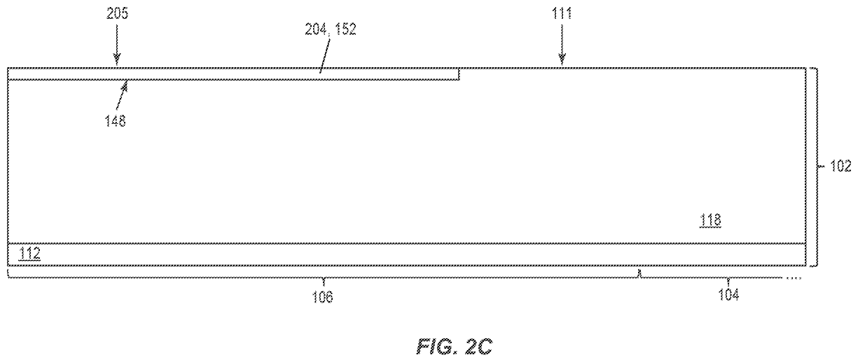

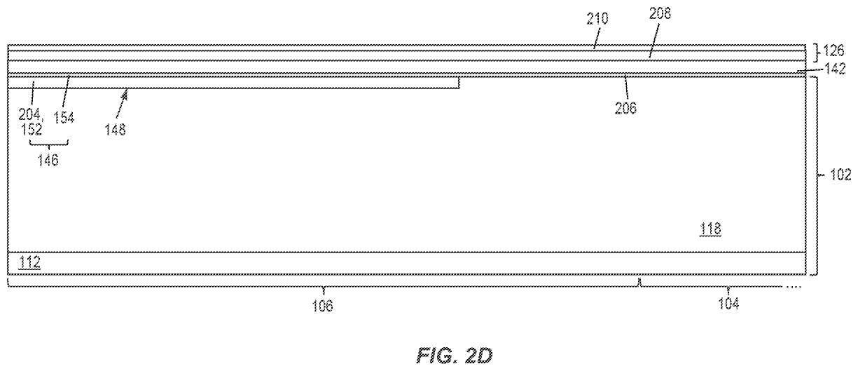

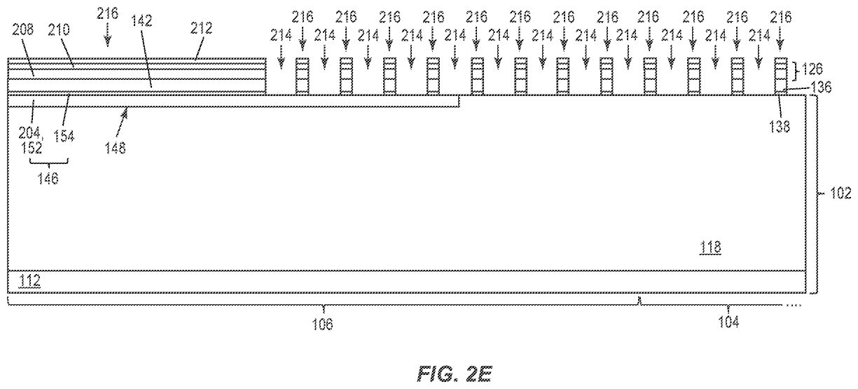

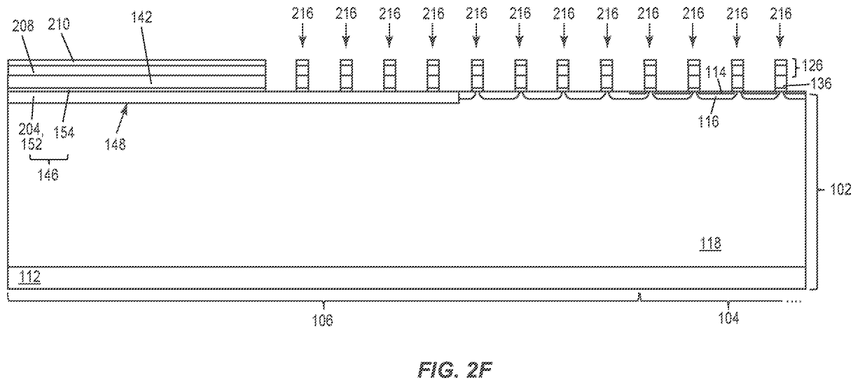

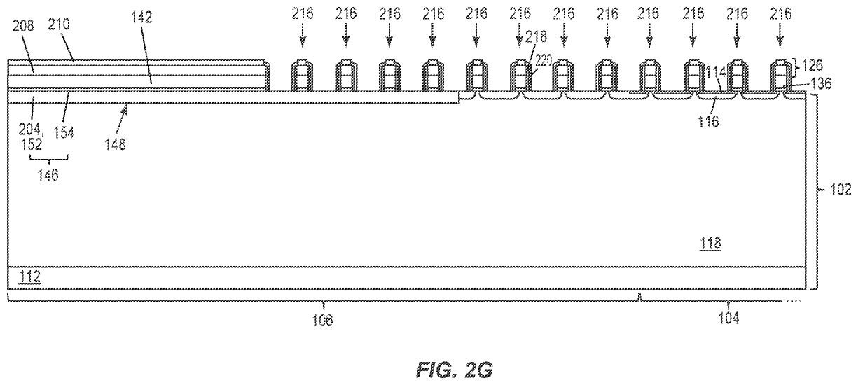

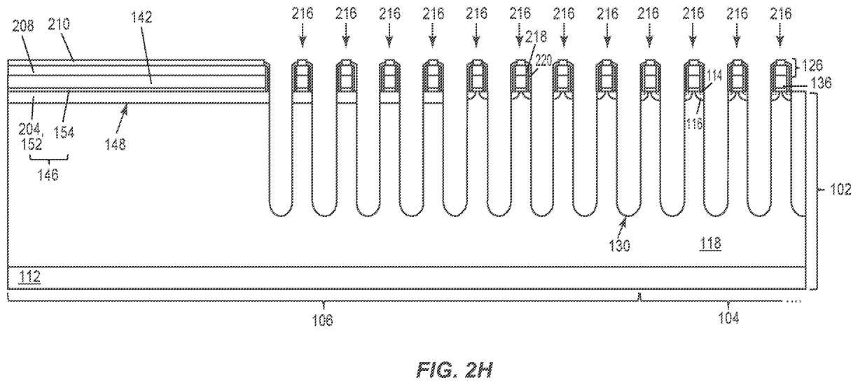

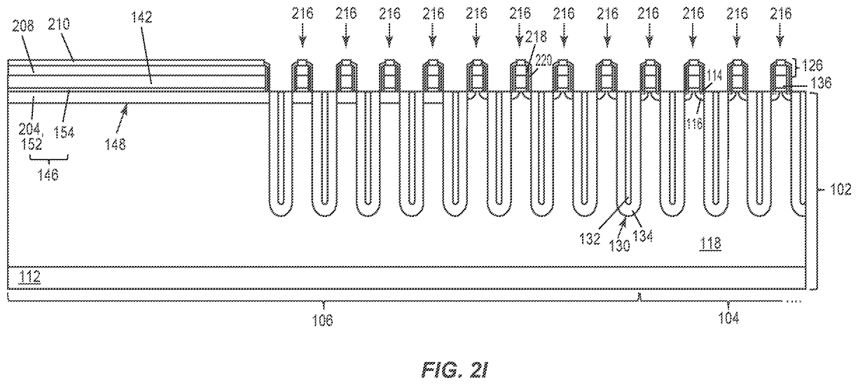

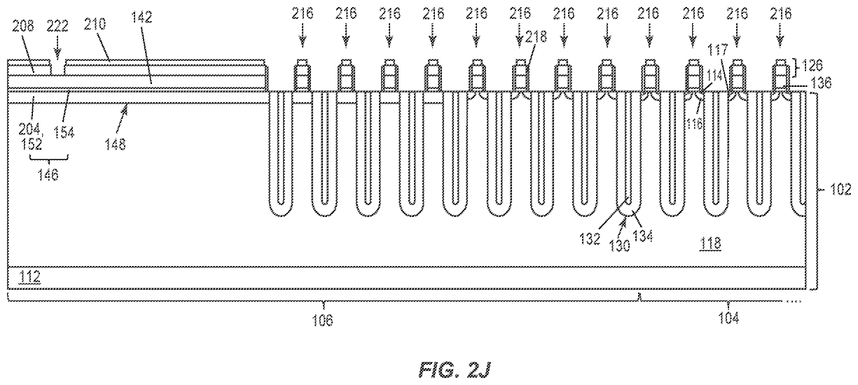

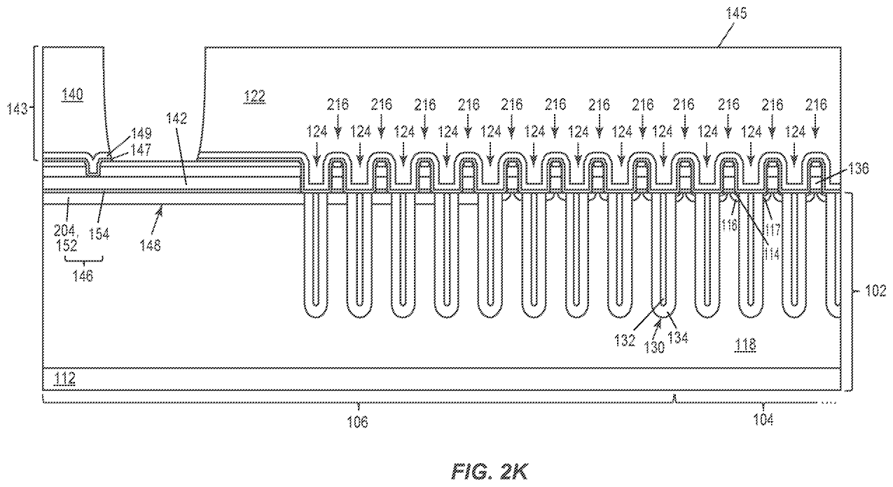

FIGS. 2A through 2K illustrate the same partial cross-sectional view of the semiconductor device 100 in FIG. 1 during different stages of production, according to an embodiment.

FIG. 2A shows the semiconductor substrate 102 after a mask 200 is formed on the first main surface 111 of the semiconductor substrate 102. The mask 200 has an opening 202 that corresponds to the part of the termination region 106 where the shielding layer 146 is to be formed. In one embodiment, the mask 200 is a photomask.

FIG. 2B shows the semiconductor substrate 102 after etching of the semiconductor substrate 102 at the first main surface 111 through the opening 202 in the mask 200 to form a recess 148 in the termination region 106 where the shielding layer 146 is to be formed. The depth D_rec of the recess 148 as measured from the unetched first main surface 111 of the semiconductor substrate 102 depends on the desired thickness of the shielding layer 146, and the etch process is controlled in a corresponding manner. For example, the recess depth D_rec may be at least 0.5 μm (microns).

FIG. 2C shows the semiconductor substrate 102 after the mask 200 is removed and the recess 148 in the termination region 106 is filled with an oxide 204 that forms the first (lower) oxide 152 of the shielding layer 146. In one embodiment, the oxide 204 is formed by STI and then planarized, e.g., by CMP such that the upper surface 205 of the oxide 204 in the termination region 106 is coplanar with the first main surface 111 of the semiconductor substrate 102 in the active device region 104. In another embodiment, the oxide 204 is formed by LOCOS. In this case, the upper surface 205 of the oxide 204 would not be coplanar with the first main surface 111 of the semiconductor substrate 102.

FIG. 2D shows the semiconductor substrate 102 after formation of a gate oxide layer 206 on the oxide 204 in the recess 148 and on the first main surface 111 elsewhere, deposition of the gate polysilicon layer 142 on the gate oxide layer 206 in both the active device region 104 and the termination region 106, and formation of the interlayer dielectric 126 on the gate polysilicon layer 142. The gate oxide layer 206 may be deposited, thermally grown, or a combination of both. The second oxide 154 of the shielding layer oxide 146 may be formed from the gate oxide layer 206 or a different oxide. The interlayer dielectric 126 may comprise a single material such as an oxide 208 or more than one material such as a nitride 210 formed on the oxide 208.

FIG. 2E shows the semiconductor substrate 102 after a mask 212 is formed on the interlayer dielectric 126 and etching through the interlayer dielectric 126, the polysilicon layer 142 and the gate oxide layer 206 through openings 214 in the mask 212 to form material stacks 216 on the first main surface 111 in the active device region 104 and on the oxide 204 in the recess 148 in the termination region 106. Each material stack 216 includes part of the interlayer dielectric 126 and part of the polysilicon layer 142. The part of the polysilicon layer 142 that remains in the material stacks 216 in the active device region 104 forms the gate electrodes 136 of the transistor cells 110, and the part of the gate oxide layer 206 that remains in the material stacks 216 in the active device region 104 forms the corresponding gate dielectric 138. The part of the gate oxide layer 206 that remains in the material stacks 216 in the termination region 106 forms the second oxide 154 of the shielding layer 146 in this embodiment.

FIG. 2F shows the semiconductor substrate 102 after removal of the mask 212 and formation of the source/emitter regions 114 of the first conductivity type and the body regions 116 of the second conductivity type in the active device region 104. The source/emitter regions 114 are formed by implanting a dopant species of the first conductivity into the semiconductor substrate 102 between the material stacks 216 in the active region. The body regions 116 are similarly formed by implanting a dopant species of the second conductivity into the semiconductor substrate 102 between the material stacks 216. As previously explained herein, the active device region 104 is where fully functional device cells 110 are formed and the termination region 106 is devoid of fully functional device cells. Accordingly, the body implant may be performed in both the termination region 106 and the active device region 104 but the source/emitter implant is blocked in the termination region 106.

FIG. 2G shows the semiconductor substrate 102 after forming an oxide spacer 218 on the sidewalls of the material stacks 218 and a nitride spacer 220 on the oxide spacer 218.

FIG. 2H shows the semiconductor substrate 102 after etching into the semiconductor substrate 102 between the material stacks 216 to form the needle-shaped field plate trenches 130. The etching in the termination region 106 includes etching through the oxide 204 in the recess 148. In one embodiment, the oxide 204 in the recess 148 is etched through first in the termination region 106 followed by etching into the semiconductor substrate 102 in both the active device region 104 and the termination region 106.

FIG. 2I shows the semiconductor substrate 102 after formation of the field dielectric insulating material 134 and the field electrodes 132 in the needle-shaped field plate trenches 130. The field dielectric insulating material 134 may be a deposited oxide, a thermally grown oxide, or a combination of both. The field electrodes 132 may comprise polysilicon, for example. The field oxide(s) and field plate material are planarized, e.g., by CMP and then recess etched to limit the field dielectric insulating material 134 and the field electrodes 132 to the needle-shaped field plate trenches 130. The CMP may stop on the nitride 210 of the interlayer dielectric 126.

FIG. 2J shows the semiconductor substrate 102 after removal of the nitride spacer 220 from the sidewalls of the material stacks 216, an oxide recess etch, and an anisotropic etch of the exposed semiconductor substrate 102. The nitride spacer 220 may be removed after the material for the field dielectric insulating material 134 and the material for the field electrodes 132 are recess etched. An opening 222 is formed that extends through the interlayer dielectric 126 to expose the polysilicon layer 142 in the termination region 106. Highly doped body contact regions 117 may be implanted into the upper surface of the body regions 116 to enable an ohmic connection to the body regions 116.

FIG. 2K shows the semiconductor substrate 102 after formation of the structured power metallization 143. The structured power metallization 143 may be formed by blanket depositing a diffusion barrier and/or adhesion promoter 147 such as Ti and/or TiN on the interlayer dielectric 126. A blanket tungsten layer 149 is deposited on the blanket diffusion barrier and/or adhesion promoter 147. The blanket tungsten layer 149 electrically contacts the field electrodes 132 in the needle-shaped field plate trenches 130 and the source and body regions 114, 116 of the transistor cells 110 between the material stacks 216. The blanket tungsten layer 149 also electrically contacts the polysilicon layer 142 through the opening 222 that extends through the interlayer dielectric 126 in the termination region 106.

A blanket power metal layer 145 that comprises Cu, Al, AlCu, AlSiCu, etc. is deposited on the blanket tungsten layer 149. The blanket power metal layer 145 is substantially thicker than the blanket tungsten layer 149 and the blanket diffusion barrier and/or adhesion promoter 147. For example, the blanket diffusion barrier and/or adhesion promoter 147 may comprise a Ti layer having a thickness of about 30 nm and a TiN layer having a thickness of about 40 nm. The blanket tungsten layer 149 may be about 300 nm thick. The blanket power metal layer 145 may be about 5 μm thick. These are just examples, though, and other thicknesses fall within the scope of the gate interconnection design embodiments described herein.

The blanket metal layers 145, 147, 149 of the power metallization 143 are then patterned by etching to define the gate metallization 140 and the source/emitter metallization 122 which are electrically isolated from one another. At least part of the gate metallization 140 forms a gate contact pad for external contacting by a gate conductor (not shown) such as one or more bond wires or a metal clip. The gate pad contact pad 140 is electrically connected to the polysilicon layer 142 in the termination region 106 and thus to the gate electrodes 136 in the active device region 104. At least part of the source/emitter metallization 122 forms a source/emitter contact pad for external contacting by a source/emitter conductor (not shown) such as a plurality of bond wires or a metal clip. The source/emitter pad contact pad 122 is electrically connected to the source and body regions 114, 116 in the active device region 104 and to the field electrodes 132 in both the termination region 106 and the active device region 104.

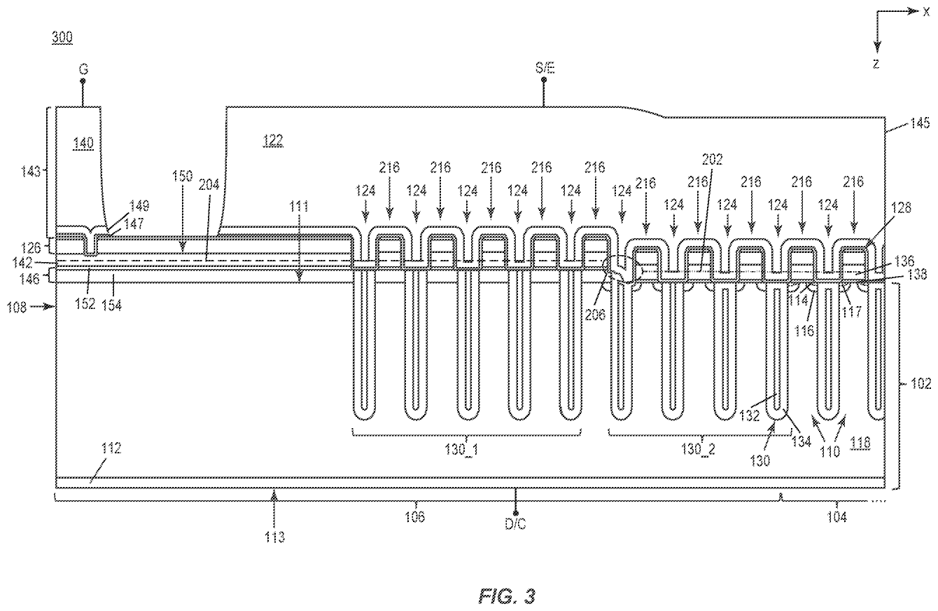

FIG. 3 illustrates a partial cross-sectional view of another semiconductor device 300 with the gate interconnection design. The semiconductor device 300 shown in FIG. 3 is similar to the semiconductor device 100 shown in FIG. 1. In FIG. 3, the lower oxide 154 of the shielding layer 146 is disposed on the first main surface 111 of the semiconductor substrate 102 in the termination region 106. The polysilicon layer 142 lies in a first (lower) plane 202 above the active device region 104 and in a second (higher) plane 204 above the termination region 106, where the second plane 204 is spaced further from the first main surface 111 than the first plane 202. Accordingly, the polysilicon layer 142 transitions from a first level in the active region 104 to a second level in the termination region 106 in a transition or step region 206 with the first level being closer to the semiconductor substrate 102 than the second level. The transition of the polysilicon layer 142 from one level to another occurs in a region 206 where the lower oxide 154 of the shielding layer 146 ends, since the shielding layer 146 is formed on the first main surface 111 of the semiconductor substrate 102 in FIG. 3 instead of in a recess 148 as illustrated in FIG. 1.

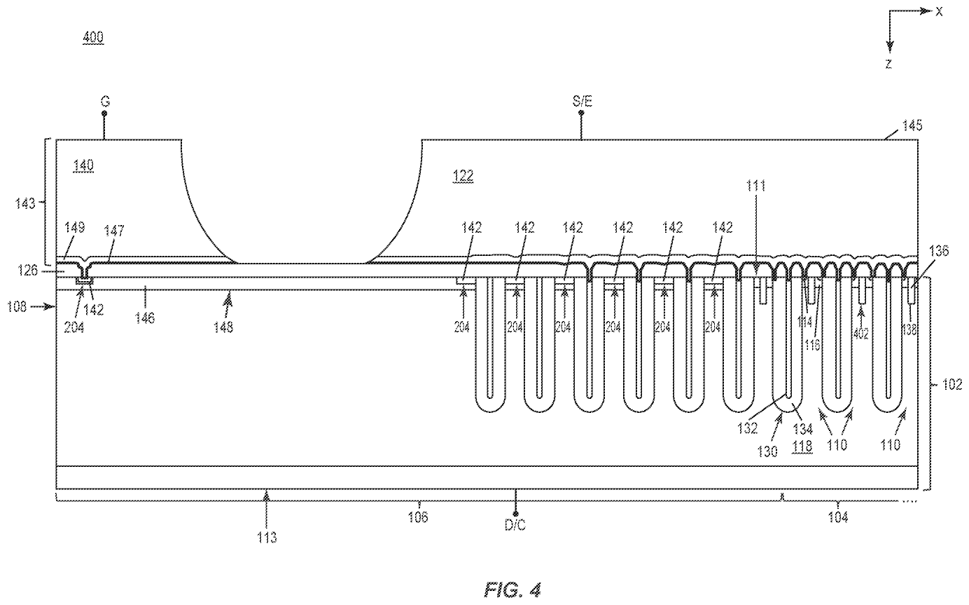

FIG. 4 illustrates a partial cross-sectional view of another semiconductor device 400 with the gate interconnection design. The semiconductor device 400 shown in FIG. 4 is a gate trench device instead of a planar gate device like in FIGS. 1 and 3. Accordingly, the gate electrodes 136 and corresponding gate dielectric 138 in the transistor cells 110 are disposed in gate trenches 402 that extend from the first main surface 111 into the semiconductor substrate 102 in an active device region 104.

Similar to what is shown in FIG. 1, the shielding layer 146 is disposed in a recess 148 in the termination region 106. The shielding layer 146 has a higher dielectric strength than just the gate dielectric 138, as previously explained herein. In FIG. 4, the polysilicon 142 is disposed in recesses 204 formed in the shielding layer 146. The polysilicon 142 is insulated from the semiconductor substrate 102 by the shielding layer 146 and electrically connected to the gate electrodes 136 in the active region 104.

Although the present disclosure is not so limited, the following numbered examples demonstrate one or more aspects of the disclosure.

Example 1. A semiconductor device, comprising: a semiconductor substrate; a plurality of transistors cells in an active device region of the semiconductor substrate, each transistor cell having a gate electrode separated from the semiconductor substrate by a gate dielectric; a plurality of needle-shaped field plate trenches in the active device region and in a termination region of the semiconductor substrate that is devoid of fully functional transistor cells; a polysilicon layer that forms the gate electrodes in the active device region and extends over at least part of the termination region; and a shielding layer that separates the polysilicon layer from the semiconductor substrate in the termination region, the shielding layer having a higher dielectric strength than just the gate dielectric.

Example 2. The semiconductor device of example 1, wherein the plurality of needle-shaped field plate trenches extends from a first main surface of the semiconductor substrate into the semiconductor substrate, wherein the first main surface has a recess in the termination region, and wherein the shielding layer is an oxide disposed in the recess.

Example 3. The semiconductor device of example 2, wherein the first main surface of the semiconductor substrate and an upper surface of the oxide are coplanar, and wherein the polysilicon layer lies in a same plane above both the active device region and the termination region.

Example 4. The semiconductor device of any of examples 1 through 3, wherein the shielding layer is an oxide, and wherein the oxide is disposed partly below the first main surface and partly above the first main surface in the termination region.

Example 5. The semiconductor device of any of examples 1 through 4, wherein the plurality of needle-shaped field plate trenches extends from a first main surface of the semiconductor substrate into the semiconductor substrate, wherein the shielding layer is an oxide disposed on the first main surface in the termination region, wherein the polysilicon layer lies in a first plane above the active device region and in a second plane above the termination region, and wherein the second plane is spaced further from the first main surface than the first plane.

Example 6. The semiconductor device of any of examples 1 through 5, wherein the shielding layer comprises a first oxide that contacts the semiconductor substrate in the termination region and a second oxide formed on the first oxide.

Example 7. The semiconductor device of any of examples 1 through 6, wherein the plurality of needle-shaped field plate trenches extends from a first main surface of the semiconductor substrate into the semiconductor substrate, and wherein at least some of the needle-shaped field plate trenches in the termination region extend through the shielding layer.

Example 8. The semiconductor device of example 7, wherein a first subset of the needle-shaped field plate trenches in the termination region extend through the shielding layer, and wherein a second subset of the needle-shaped field plate trenches in the termination region extend only in semiconductor material.

Example 9. The semiconductor device of any of examples 1 through 8, wherein the polysilicon layer transitions from a first level in the active device region to a second level in the termination region, and wherein the first level is closer to the semiconductor substrate than the second level.

Example 10. The semiconductor device of any of examples 1 through 9, wherein: the semiconductor substrate has an edge that extends between first and second main surfaces of the semiconductor substrate; the termination region is interposed between the active device region and the edge; the plurality of needle-shaped field plate trenches extends from the first main surface into the semiconductor substrate; the gate electrodes are disposed above the first main surface; and the polysilicon layer lies in a same plane above both the active device region and the termination region.

Example 11. The semiconductor device of any of examples 1 through 10, wherein: the semiconductor substrate has an edge that extends between first and second main surfaces of the semiconductor substrate; the termination region is interposed between the active device region and the edge; the plurality of needle-shaped field plate trenches extend from the first main surface into the semiconductor substrate; the gate electrodes are disposed above the first main surface; the shielding layer is a dielectric material disposed on the first main surface in the termination region; and the polysilicon layer lies in a lower plane above the active device region and in a higher plane above the termination region.

Example 12. A semiconductor device, comprising: a semiconductor substrate having an edge that extends between first and second main surfaces of the semiconductor substrate; a plurality of gate trenches extending from the first main surface into the semiconductor substrate in an active device region of the semiconductor substrate, each gate trench including a gate electrode insulated from the semiconductor substrate by a gate dielectric; a plurality of needle-shaped field plate trenches extending from the first main surface into the semiconductor substrate in both the active device region and a termination region of the semiconductor substrate that is devoid of fully functional transistor cells, the termination region having a recess formed in the first main surface; a shielding layer disposed in the recess in the termination region, the shielding layer having a higher dielectric strength than just the gate dielectric; polysilicon disposed in recesses formed in the shielding layer, the polysilicon being insulated from the semiconductor substrate by the shielding layer and electrically connected to the gate electrodes in the active device region.

Example 13. A method of fabricating semiconductor devices from a semiconductor wafer, the method comprising: forming a plurality of transistors cells in an active device region of the semiconductor substrate, each transistor cell having a gate electrode separated from the semiconductor substrate by a gate dielectric; forming a plurality of needle-shaped field plate trenches in the active device region and in a termination region of the semiconductor substrate that is devoid of fully functional transistor cells; forming a polysilicon layer that forms the gate electrodes in the active device region and extends over at least part of the termination region; and forming a shielding layer that separates the polysilicon layer from the semiconductor substrate in the termination region, the shielding layer having a higher dielectric strength than just the gate dielectric.

Example 14. The method of example 13, wherein forming the shielding layer comprises: etching a recess into a first main surface of the semiconductor substrate in the termination but not in the active device region; and filling the recess with an oxide.

Example 15. The method of example 14, further comprising: planarizing the oxide such that the first main surface of the semiconductor substrate and an upper surface of the oxide are coplanar before forming the plurality of transistors cells, the plurality of needle-shaped field plate trenches, and the polysilicon layer.

Example 16. The method of example 14 or 15, wherein forming the polysilicon layer comprises: forming a gate oxide layer on the oxide in the recess and on the first main surface elsewhere; and depositing polysilicon on the gate oxide material in both the active device region and the termination region.

Example 17. The method of example 16, wherein forming the plurality of needle-shaped field plate trenches comprises: forming an interlayer dielectric on the polysilicon layer; etching through the interlayer dielectric, the polysilicon layer, and the gate oxide layer to form material stacks on the first main surface in the active device region and on the oxide in the recess in the termination region; and etching into the semiconductor substrate between the material stacks, wherein the etching in the termination region includes etching through the oxide in the recess.

Example 18. The method of example 17, wherein forming the plurality of transistors cells comprises: implanting body regions and source regions into the semiconductor substrate between the material stacks in the active device region, wherein the portion of the polysilicon layer that remains in the material stacks in the active device region forms planar gate electrodes that are separated from the first main surface by the gate oxide layer.

Example 19. The method of example 18, further comprising: after implanting the body regions and the source regions and before etching into the semiconductor substrate between the material stacks to form the plurality of needle-shaped field plate trenches, forming an oxide spacer on sidewalls of the material stacks and a nitride spacer on the oxide spacer.

Example 20. The method of any of examples 17 through 19, further comprising: forming an opening that extends through the interlayer dielectric to expose the polysilicon layer in the termination region; forming a blanket tungsten layer over the semiconductor wafer so that the blanket tungsten layer electrically contacts field electrodes in the needle-shaped field plate trenches and source and body regions of the transistor cells between the material stacks, and electrically contacts the polysilicon layer through the opening that extends through the interlayer dielectric in the termination region; forming a blanket power metal layer on the blanket tungsten layer; and patterning the blanket power metal layer and the blanket tungsten layer to provide a first contact pad for the field electrodes and the source and body regions, and a second contact pad for the polysilicon layer.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate;
a plurality of transistors cells in an active device region of the semiconductor substrate, each transistor cell having a gate electrode separated from the semiconductor substrate by a gate dielectric;
a plurality of needle-shaped field plate trenches in the active device region and in a termination region of the semiconductor substrate that is devoid of fully functional transistor cells;
a polysilicon layer that forms the gate electrodes in the active device region and extends over at least part of the termination region; and
a shielding layer that separates the polysilicon layer from the semiconductor substrate in the termination region, the shielding layer having a higher dielectric strength than just the gate dielectric.

2. The semiconductor device of claim 1, wherein the plurality of needle-shaped field plate trenches extends from a first main surface of the semiconductor substrate into the semiconductor substrate, wherein the first main surface has a recess in the termination region, and wherein the shielding layer is an oxide disposed in the recess.

3. The semiconductor device of claim 2, wherein the first main surface of the semiconductor substrate and an upper surface of the oxide are coplanar, and wherein the polysilicon layer lies in a same plane above both the active device region and the termination region.

4. The semiconductor device of claim 1, wherein the shielding layer is an oxide, and wherein the oxide is disposed partly below the first main surface and partly above the first main surface in the termination region.

5. The semiconductor device of claim 1, wherein the plurality of needle-shaped field plate trenches extends from a first main surface of the semiconductor substrate into the semiconductor substrate, wherein the shielding layer is an oxide disposed on the first main surface in the termination region, wherein the polysilicon layer lies in a first plane above the active device region and in a second plane above the termination region, and wherein the second plane is spaced further from the first main surface than the first plane.

6. The semiconductor device of claim 1, wherein the shielding layer comprises a first oxide that contacts the semiconductor substrate in the termination region and a second oxide formed on the first oxide.

7. The semiconductor device of claim 1, wherein the plurality of needle-shaped field plate trenches extends from a first main surface of the semiconductor substrate into the semiconductor substrate, and wherein at least some of the needle-shaped field plate trenches in the termination region extend through the shielding layer.

8. The semiconductor device of claim 7, wherein a first subset of the needle-shaped field plate trenches in the termination region extend through the shielding layer, and wherein a second subset of the needle-shaped field plate trenches in the termination region extend only in semiconductor material.

9. The semiconductor device of claim 1, wherein the polysilicon layer transitions from a first level in the active device region to a second level in the termination region, and wherein the first level is closer to the semiconductor substrate than the second level.

10. The semiconductor device of claim 1, wherein:
the semiconductor substrate has an edge that extends between first and second main surfaces of the semiconductor substrate;
the termination region is interposed between the active device region and the edge;
the plurality of needle-shaped field plate trenches extends from the first main surface into the semiconductor substrate;
the gate electrodes are disposed above the first main surface; and
the polysilicon layer lies in a same plane above both the active device region and the termination region.

11. The semiconductor device of claim 1, wherein:
the semiconductor substrate has an edge that extends between first and second main surfaces of the semiconductor substrate;
the termination region is interposed between the active device region and the edge;
the plurality of needle-shaped field plate trenches extend from the first main surface into the semiconductor substrate;
the gate electrodes are disposed above the first main surface;
the shielding layer is a dielectric material disposed on the first main surface in the termination region; and
the polysilicon layer lies in a lower plane above the active device region and in a higher plane above the termination region.

12. A semiconductor device, comprising:
a semiconductor substrate having an edge that extends between first and second main surfaces of the semiconductor substrate;
a plurality of gate trenches extending from the first main surface into the semiconductor substrate in an active device region of the semiconductor substrate, each gate trench including a gate electrode insulated from the semiconductor substrate by a gate dielectric;
a plurality of needle-shaped field plate trenches extending from the first main surface into the semiconductor substrate in both the active device region and a termination region of the semiconductor substrate that is devoid of fully functional transistor cells, the termination region having a recess formed in the first main surface;
a shielding layer disposed in the recess in the termination region, the shielding layer having a higher dielectric strength than just the gate dielectric;
polysilicon disposed in recesses formed in the shielding layer, the polysilicon being insulated from the semiconductor substrate by the shielding layer and electrically connected to the gate electrodes in the active device region.

13. A method of fabricating semiconductor devices from a semiconductor wafer, the method comprising:
forming a plurality of transistors cells in an active device region of the semiconductor substrate, each transistor cell having a gate electrode separated from the semiconductor substrate by a gate dielectric;
forming a plurality of needle-shaped field plate trenches in the active device region and in a termination region of the semiconductor substrate that is devoid of fully functional transistor cells;
forming a polysilicon layer that forms the gate electrodes in the active device region and extends over at least part of the termination region; and
forming a shielding layer that separates the polysilicon layer from the semiconductor substrate in the termination region, the shielding layer having a higher dielectric strength than just the gate dielectric.

14. The method of claim 13, wherein forming the shielding layer comprises:
etching a recess into a first main surface of the semiconductor substrate in the termination but not in the active device region; and
filling the recess with an oxide.

15. The method of claim 14, further comprising:
planarizing the oxide such that the first main surface of the semiconductor substrate and an upper surface of the oxide are coplanar before forming the plurality of transistors cells, the plurality of needle-shaped field plate trenches, and the polysilicon layer.

16. The method of claim 14, wherein forming the polysilicon layer comprises:
forming a gate oxide layer on the oxide in the recess and on the first main surface elsewhere; and
depositing polysilicon on the gate oxide material in both the active device region and the termination region.

17. The method of claim 16, wherein forming the plurality of needle-shaped field plate trenches comprises:
forming an interlayer dielectric on the polysilicon layer;
etching through the interlayer dielectric, the polysilicon layer, and the gate oxide layer to form material stacks on the first main surface in the active device region and on the oxide in the recess in the termination region; and
etching into the semiconductor substrate between the material stacks,
wherein the etching in the termination region includes etching through the oxide in the recess.

18. The method of claim 17, wherein forming the plurality of transistors cells comprises:
implanting body regions and source regions into the semiconductor substrate between the material stacks in the active device region,
wherein the portion of the polysilicon layer that remains in the material stacks in the active device region forms planar gate electrodes that are separated from the first main surface by the gate oxide layer.

19. The method of claim 18, further comprising:
after implanting the body regions and the source regions and before etching into the semiconductor substrate between the material stacks to form the plurality of needle-shaped field plate trenches, forming an oxide spacer on sidewalls of the material stacks and a nitride spacer on the oxide spacer.

20. The method of claim 17, further comprising:
forming an opening that extends through the interlayer dielectric to expose the polysilicon layer in the termination region;
forming a blanket tungsten layer over the semiconductor wafer so that the blanket tungsten layer electrically contacts field electrodes in the needle-shaped field plate trenches and source and body regions of the transistor cells between the material stacks, and electrically contacts the polysilicon layer through the opening that extends through the interlayer dielectric in the termination region;
forming a blanket power metal layer on the blanket tungsten layer; and
patterning the blanket power metal layer and the blanket tungsten layer to provide a first contact pad for the field electrodes and the source and body regions, and a second contact pad for the polysilicon layer.
